(19) United States
(12) Patent Application Publication
(10) Pub. No.: US 2012/0161949 A1
(43) Pub. Date: Jun. 28, 2012

(54) ACUATOR SYSTEMS AND METHODS USING AN ELECTRICALLY DEFORMABLE MATERIAL

(75) Inventor: Hin Sing FONG, Singapore (SG)

(73) Assignee: STMICROELECTRONICS ASIA PACIFIC PTE LTD., Singapore (SG)

(21) Appl. No.: 12/980,242

(22) Filed: Dec. 28, 2010

(51) Int. Cl. G08B 6/00; H01L 41/02

(52) U.S. Cl. 340/407.2; 310/328

(57) ABSTRACT

Actuation systems and devices using an electrically deformable material are disclosed. In the embodiments, a bidirectional actuator assembly includes a first unit including an electrically deformable material coupleable to an activation voltage and configured to provide a displacement in a first direction when the activation voltage is applied to the first unit. A second unit is serially electrically coupled to the first unit and includes an electrically deformable material coupleable to the activation voltage and configured to provide a displacement in a second direction that is different from the first direction when the activation voltage is applied to the second unit. A unidirectional actuator assembly includes at least one unit including an electrically deformable material coupleable to an activation voltage, wherein the electrically deformable material provides a displacement in a selected direction when the activation voltage is applied to the at least one unit.

### TECHNICAL FIELD

This disclosure relates generally to actuation systems and devices, and more particularly to actuation systems and devices using an electrically deformable material.

### BACKGROUND

In many current technologies, actuators that provide a mechanical motion in response to contacting a suitably configured touch-sensitive interface are desired. A significant technical impediment in the development of touch sensitive interfaces of reduced scale, mass and power consumption may include reducing the number of discrete components of fixed size that may form a portion of the actuators. In applications where a plurality of the actuators may be present in large groups, a reduction in the number of fixed-size components may therefore lead to significant savings in weight, dimensional size, power consumption and cost of the interface.

### SUMMARY

Actuation systems and devices using an electrically deformable material are disclosed. In accordance with various aspects, a bidirectional actuator assembly includes a first unit including an electrically deformable material coupleable to an activation voltage and configured to provide a displacement in a first direction when the activation voltage is applied to the first unit. A second unit is serially electrically coupled to the first unit and includes an electrically deformable material coupleable to the activation voltage and configured to provide a displacement in a second direction that is different from the first direction when the activation voltage is applied to the second unit.

In accordance with other aspects, a unidirectional actuator assembly may include at least one unit including an electrically deformable material coupleable to an activation voltage, wherein the electrically deformable material provides a displacement in a selected direction when the activation voltage is applied to the at least one unit.

In accordance with still other aspects, a method of operating a bidirectional actuator assembly may include initializing a first actuator and a second actuator, wherein the first actuator and the second actuator may include an electrically deformable material, applying an actuation voltage to the first actuator to generate a displacement in a first direction, and applying an actuation voltage to the second actuator to generate a displacement in a second direction that is different from the first direction. A method of operating a unidirectional actuator assembly may include initializing an actuator that includes an electrically deformable material, and applying an actuation voltage to the actuator to generate a displacement in a selected direction.

In still yet other aspects, an actuator system may include at least one group, which may further include a power switch in communication with an activation voltage, and an array of blocks arranged in rows and columns, each block having an electrically deformable material responsive to the activation voltage and configured to provide a displacement in at least one direction upon actuation. A method of operating an actuator system may include selecting a group having an array of blocks arranged in rows and columns, selecting at least one block within the group, each block having at least one actuator switch electrically coupled in parallel with an actuator having an electrically deformable material configured to generate a displacement in an actuation direction in response to an activation voltage, configuring the row and the column in the group that includes the selected at least one block, and applying the activation voltage to the selected at least one block.

In another aspect, a computer system may include a computing device, at least one input/output device coupled to the computing device including at least one touch-actuated control, which may further include an actuator including an electrically deformable material that is selectively coupleable to an activation voltage through an actuator switch, wherein the electrically deformable material is configured to provide a displacement in a selected direction when the activation voltage is applied to the electrically deformable material.

### BRIEF DESCRIPTION OF THE DRAWINGS

Various embodiments are described in detail in the discussion below and with reference to the following drawings.

FIG. 1 is a diagrammatic block view of a bidirectional actuator assembly according to the various embodiments.

FIG. 2 is a diagrammatic block view of a unidirectional actuator assembly according to the various embodiments.

FIG. 3 is a table that will be used to describe various operating modes for the bidirectional and unidirectional actuator assemblies, according to the various embodiments.

FIG. 4 is a table that will be used to describe various operating mode sequences for the bidirectional and unidirectional actuator assemblies, according to the various embodiments.

FIG. 5 is a flowchart describing a method of operating a bidirectional actuator assembly, according to the various embodiments.

FIG. 6 is a flowchart describing a method of operating a unidirectional actuator assembly, according to the various embodiments.

FIG. 7 is a diagrammatic block view of an actuator system, according to the various embodiments.

FIG. 8 is a flowchart describing a method of operating an actuator system, according to the various embodiments.

FIG. 9 is a schematic view of a switch that may be used in a switch/actuator unit or a power switch, according to the various embodiments.

FIG. 10 is a diagrammatic block view of a computer system according to the various embodiments.

### DETAILED DESCRIPTION

Actuator systems and methods using electrically deformable materials (EDMs) are disclosed. Briefly, and in general terms, an actuator may be formed by interposing an EDM between an opposing pair of compliant electrodes. When a suitable voltage is applied to the compliant electrodes, a dimension in the direction of the thickness of the EDM decreases in response to the applied electric field, while dimensions of the EDM in respective directions transverse to the thickness of the EDM increase, in accordance with the Poisson Effect. Accordingly, the deformation of the EDM by the electric field may be used to impart an actuation force to a switch, or other displacement-actuated devices, that may be mechanically coupled to the EDM. Suitable EDMs may include a ferroelectric or piezoelectric material, including, for example, polyvinylidene fluoride (PVDF) and polyacetylene that has been doped with iodine, although other suitable materials exist. Various commercially-available electroactive polymer (EAP) materials, however, may also be used, which are configured to achieve large strains when suitably electrically biased. For example, suitable EAP materials may include the HS3 silicone compound, available from Dow Corning, Inc. of Midland, Mich., the Nusil CF 19-2186 silicone compound, available from the Nusil Corporation of Carpenteria, Calif., and the VHB 4190 acrylic compound, available from the 3M Company of St. Paul, Minn., although other suitable compounds may also be used.

Typically, the electrical bias applied to the EAP is interruptible, in order to establish a displaced condition in the EAP when the electric field is applied, and to allow the EAP to at least partially elastically return to a relaxed condition when the electric field is interrupted. Since the electric field strength required for useful dimensional displacements in EAP materials may require an applied direct current (DC) bias in the kilovolt range, switching elements having a suitable dielectric strength may be applicable. Accordingly, a single switching element may be used that is configured to have a dielectric strength in the kilovolt range, but more generally, a plurality of switching elements each having a lower dielectric strength may be serially coupled to cooperatively obtain a switching element having a suitable dielectric strength (e.g., in the kilovolt range). In this case, the combination of individual switching elements present in a switch/actuator unit may become quite large, which may be further multiplied when a plurality of switch/actuator units are present in an assembly of actuator units. Therefore, reducing the number of switching elements may lead to the fabrication of switch/actuator units for actuator assemblies of lower weight and cost, while providing greater reliability.

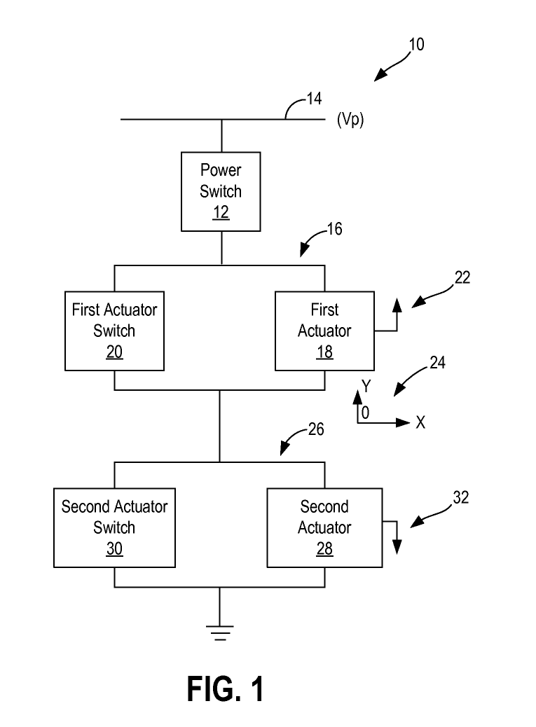

FIG. 1 is a diagrammatic block view of a bidirectional actuator assembly 10 according to the various embodiments. The bidirectional actuator assembly 10 may include a power switch 12 that may be coupled to a voltage bus 14 configured to supply an actuation voltage Vₚ that is sufficient to induce a selected displacement in an EDM. Accordingly, the actuation voltage Vₚ may range between several volts to several kilovolts, or even higher. The power switch 12 may include one or more switching devices having selectable bipolar states (e.g., an ‘open’ and a ‘closed’ state that are selectable). The selected state of the power switch 12 may be provided to the power switch 12 by a control circuit (not shown in FIG. 1) that is configured to actuate the one or more switching elements within the power switch 12 to the selected state. For example, the control circuit may be configured to respond to a change in an electrical property (e.g., a capacitance) that may be induced through tactile contact of the actuator assembly 10 by a user.

The power switch 12 may be electrically coupled to a first switch/actuator unit 16 having a first actuator 18 that may be coupled to a first actuator switch 20. The first actuator 18 may be configured to provide a displacement in a first direction 22 relative to a fixed system of coordinates 24 when the actuation voltage Vₚ is applied to the first actuator 18. Correspondingly, when the actuation voltage Vₚ is removed from the first actuator 18, the displacement may be at least partially relaxed, and the first actuator 18 may return to a non-energized position. A second switch/actuator unit 26 may include a second actuator 28 that may be coupled to a second actuator switch 30. The second actuator 28 may be configured to provide a displacement in a second direction 32 that is different from the first direction 22. According to the various embodiments, the displacement in the first direction 22 may be approximately equal to the displacement in the second direction 32. In other additional embodiments, the first direction 22 and the second direction 32 may extend in opposite directions. Alternatively, the first direction 22 and the second direction 32 may be oriented in mutually orthogonal directions, or in still other oblique angular directions. Application of the actuation voltage Vₚ to the second actuator 28 induces the second displacement 32, while removal of the actuation voltage Vₚ from the second actuator 28 may cause the displacement to be at least partially relaxed, so that the second actuator 28 may return to a non-energized position. The selected state of the first actuator switch 20 and the second actuator switch 30 may also be selected by a control circuit that is configured to actuate one or more switching elements within the first actuator switch 20 and the second actuator switch 30 to a selected state. The control circuit may again be responsive to a change in an electrical property that may be induced through tactile contact with a user.

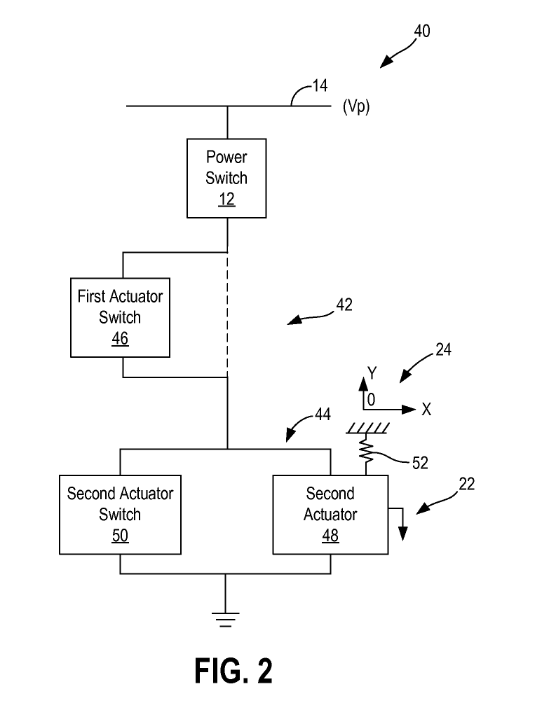

FIG. 2 is a diagrammatic block view of a unidirectional actuator assembly 40 according to the various embodiments. Since various details may have been discussed in detail previously in conjunction with other embodiments, further discussion of certain details may be omitted in the interest of brevity. The unidirectional actuator assembly 40 includes the power switch 12 that is coupled to the voltage bus 14, so that the actuation voltage Vₚ may be communicated to a first switch/actuator unit 42 and a second switch/actuator unit 44. The first switch/actuator unit 42 may include a first actuator switch 46, while the second switch/actuator unit 44 includes a second actuator 48 that is operably coupled to a second actuator switch 50. Application of the actuation voltage Vₚ to the second actuator 48 through the power switch 12 and the first actuator switch 46 may provide a displacement in the first direction 22 relative to the fixed system of coordinates 24. When the actuation voltage Vₚ is removed from the second actuator 48 by moving either the power switch 12 or the first actuator switch 46 to an open state, the displacement in the first direction 22 is relaxed, and the second actuator 48 returns to a non-energized position. In order to further urge the second actuator 48 to the non-energized position, an elastic element 52, which may include elements such as a mechanical spring, may be optionally provided in order to assist the second actuator 48 to return to the non-energized position, or to cause the second actuator 48 to return to the non-energized position within a prescribed time interval following the removal of the actuation voltage Vₚ from the second actuator 48. In the foregoing embodiment, it will be appreciated that the first actuation switch 46 may be omitted, if desired, provided that an alternative electrical path (shown in FIG. 2 as a broken line) is established, so that the actuation voltage Vₚ may be communicated to the second switch/actuator unit 44. It will also be appreciated that the first switch/actuator unit 42 may include a first actuator (not shown in FIG. 2) coupled to the first actuator switch 46, while the second actuator 48 in the second switch/actuator unit 44 is omitted. In this case, the second actuator switch 50 may be omitted, provided that electrical continuity to the ground potential is maintained, as described in detail above. Although not shown in FIG. 1 and FIG. 2, it is nevertheless understood that the first actuator 18 and the second actuator 28 of FIG. 1, and the second actuator 48 of FIG. 2 may be coupled to other displacement-responsive electromechanical devices, such as, for example, an electrical switch. The electrical switch may be configured to be either normally open or normally closed until acted upon by the first actuator 18 and the second actuator 28 of FIG. 1, and the second actuator 48 of FIG. 2. Alternatively, the electrical switch may be configured to latch a state (e.g., either an open or a closed state) when acted upon, and to unlatch the state when subsequently acted upon by the actuator. The selected state of the first actuator switch 46 or alternatively, the second actuator switch 50 may be determined by a control circuit that is configured to actuate one or more switching elements within the first actuator switch 46 or the second actuator switch 50 to a selected state. The control circuit may again be responsive to a change in an electrical property that may be induced through tactile contact with a user.

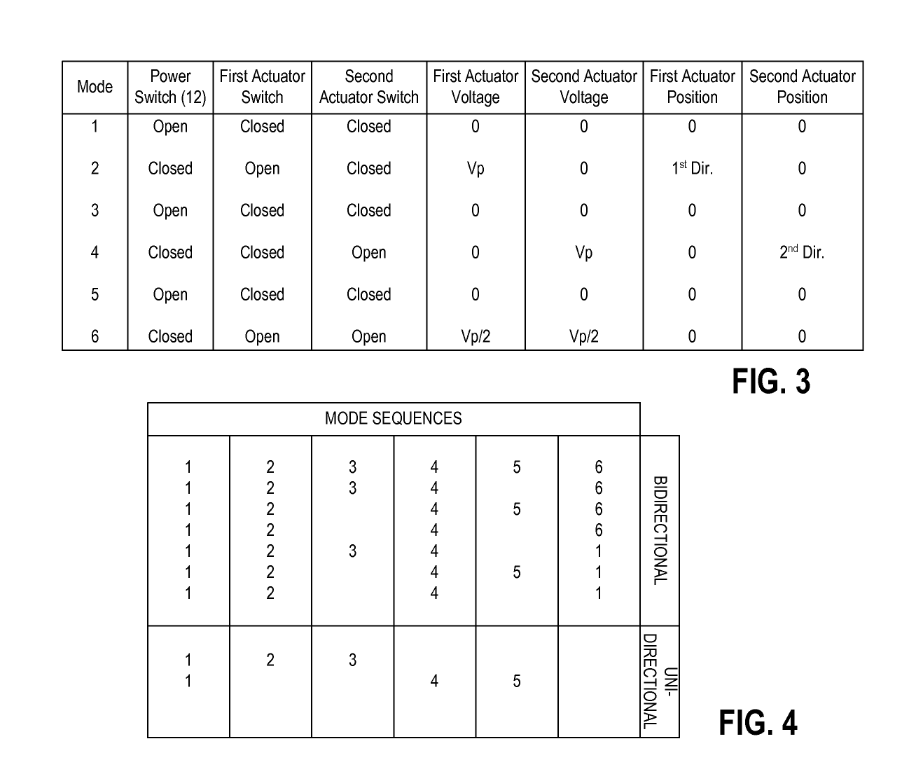

FIG. 3 is a table that will be used to describe various operating modes for the bidirectional actuator assembly 10 of FIG. 1, and the unidirectional actuator assembly 40 of FIG. 2, according to the various embodiments. With continuing reference to FIG. 1 and FIG. 2, an operating mode 1 includes opening the power switch 12, and closing the first actuator switch 20 and the second actuator switch 30, so that the first actuator 18 and the second actuator 28 are coupled to a ground potential. Accordingly, voltages applied to the first actuator 18 and the second actuator 28 are zero, so that the displacements of the first actuator 18 and the second actuator 28 at least approximately correspond to the non-energized position, respectively. Operating mode 2 includes closing the power switch 12, opening the first actuator switch 20, and closing the second actuator switch 30, so that the actuation voltage Vₚ may be applied to the first actuator 18 to cause the first actuator 18 to effect a displacement in the first direction, while the second actuator 28 remains in the non-energized position. Operating mode 4 includes closing the power switch 12, closing the first actuator switch 20, and opening the second actuator switch 30, so that the actuation voltage Vₚ may be applied to the second actuator 28 to cause the second actuator 28 to effect a displacement in the second direction, while the first actuator 18 remains in the non-energized position. Operating mode 6 includes closing the power switch 12, and opening the first actuator switch 20 and the second actuator switch 30, so that approximately one-half of the actuation voltage Vₚ may be applied to the first actuator 18 and the second actuator 28. Since the first actuator 18 and the second actuator 28 may cause respective displacements to occur in opposing directions, the net displacement within the bidirectional actuator assembly 10 approximately corresponds to the non-energized position.

Operating modes 1, 3 and 5 include substantially similar states for the power switch 12, the first actuator switch 20 and the second actuator switch 30. Operating modes 3 and 5 generally occur, however, following an operating mode (e.g., operating modes 2 and 4) where the actuation voltage Vₚ has been asserted to at least one of the first actuator 18 and the second actuator 28. Accordingly, operating modes 3 and 5 may be regarded as operating modes configured to move the first actuator 18 and the second actuator 28 to respective non-energized positions. In contrast, operating mode 6 includes applying a voltage to each of the first actuator 18 and the second actuator 28. Operating mode 6 may therefore be regarded as an energized reset mode operable to achieve a net displacement within the bidirectional actuator assembly 10 that approximately corresponds to the non-energized position.

FIG. 4 is a table that will be used to describe various operating mode sequences for the bidirectional and unidirectional actuator assemblies, according to the various embodiments. With reference also still to FIG. 3, the operating mode sequences for the bidirectional actuator assembly 10 of FIG. 1 may include all of the operating modes described in FIG. 3, or it may include fewer than all of the operating modes shown in FIG. 3. For example, either one or both of operating mode 3 or operating mode 5 may be omitted between the operating mode 2 and the operating mode 4 (e.g., between operating modes where the actuation voltage Vₚ is applied to a selected one of the first actuator 18 and the second actuator 28 of FIG. 1). Operating mode 6, which may be regarded as an energized reset mode, may also be present at the conclusion of a mode sequence, as shown in FIG. 4. Still referring to FIG. 4, the unidirectional actuator assembly of FIG. 2 may be subjected to different operating mode sequences, depending upon whether the actuator is positioned in the first switch/actuator unit 42 or the second switch/actuator unit 44 of FIG. 2. For example, in one exemplary operating mode sequence, operating modes 1, 2 and 3 may be performed, when an actuator is present in the first switch/actuator unit 42. In another operating mode sequence, the operating modes 1, 4 and 5 may be performed, when the second actuator 48 is present in the second switch/actuator unit 44. In general, operating mode 6 is not applicable to the unidirectional actuator assembly 40 of FIG. 2.

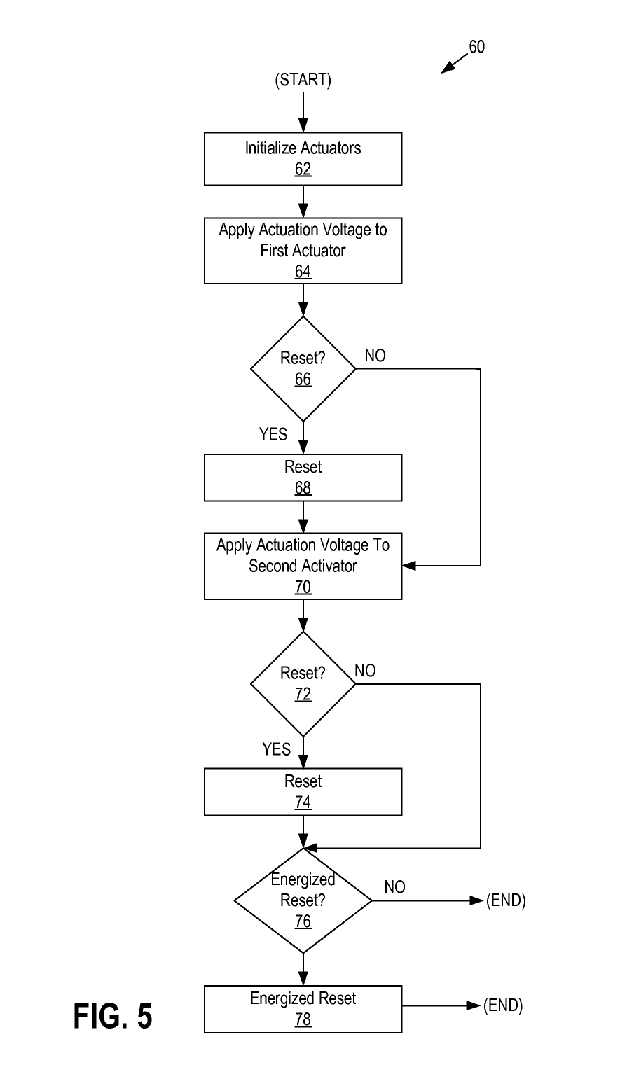

FIG. 5 is a flowchart describing a method 60 of operating a bidirectional actuator assembly, according to the various embodiments. At 62, the first actuator 18 and the second actuator 28 (FIG. 1) may be initialized by imposing operating mode 1 (FIG. 3). At 64, the actuation voltage Vₚ may be applied to the first actuator 18 by imposing operating mode 2 on the bidirectional actuator assembly 10. At decision 66, the method 60 may allow the first actuator 18 and the second actuator 28 to be reset by imposing operating mode 3 on the bidirectional actuator assembly 10, as shown at 68. Alternatively, decision 66 may branch to 70, where the actuation voltage Vₚ may be applied to the second actuator 28 by imposing operating mode 4 on the bidirectional actuator assembly 10. At decision 72, the method 60 may allow the first actuator 18 and the second actuator 28 to again be reset by imposing operating mode 5, as shown at 74. Decision 66 may also branch to decision 76, which may then cause an energized reset at 78 for the bidirectional actuator assembly 10. Alternatively, the decision 76 may cause the method 60 to end.

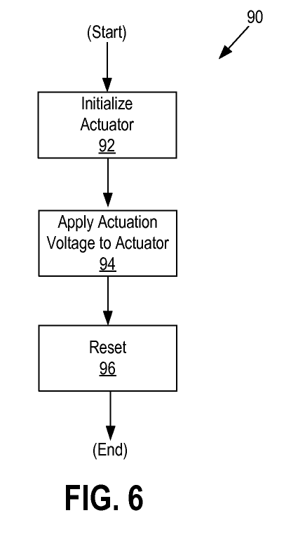

FIG. 6 is a flowchart describing a method 90 of operating a unidirectional actuator assembly, according to the various embodiments. At 92, the second actuator 48 (FIG. 2) may be initialized by imposing operating mode 1 (FIG. 3). At 94, the actuation voltage Vₚ may be applied to the second actuator 48 by imposing operating mode 2 (or operating mode 4) on the unidirectional actuator assembly 40. At 96, the second actuator 48 may be reset by imposing operating mode 3 or operating mode 5 on the unidirectional actuator assembly 40. As discussed in detail previously, the second actuator 48 in the unidirectional actuator assembly 40 may be omitted, and alternatively, a substantially similar actuator may be positioned within the first switch/actuator unit 42. Accordingly, at 92, operating mode 1 may be imposed on an actuator positioned within the first switch/actuator unit 42, and be reset at 96.

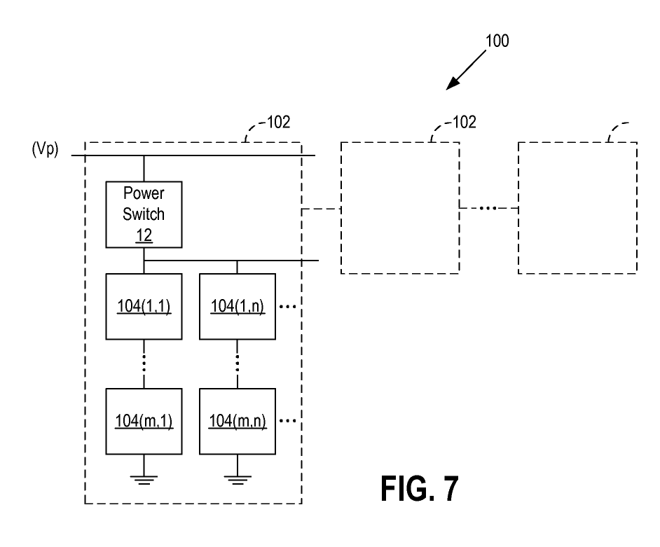

FIG. 7 is a diagrammatic block view of an actuator system 100, according to the various embodiments. The actuator system 100 may include one or more groups 102. Each of the one or more groups 102 may include a power switch 12, as discussed in connection with FIG. 1 and FIG. 2, which may be coupled to the actuation voltage Vₚ. Each group 102 may also include a plurality of switch/actuator blocks 104(1,1) through 104(m,n) that may be arranged within the group 102 as an array having m rows and n columns, for example. Each of the switch/actuator blocks 104(1,1) through 104(m,n) may include the first switch/actuator unit 16 and the second switch/actuator unit 26 of FIG. 1. Alternatively, the switch/actuator blocks 104(1,1) through 104(m,n) may include the first switch/actuator unit 42 and the second switch/actuator unit 44 of FIG. 2. In accordance with the various embodiments, one or more of the groups 102 may include a single row of the switch/actuator blocks 104(1,1) through 104(m,n). One or more of the groups 102 may include a single column of the switch/actuator blocks 104(1,1) through 104(m,n). In still other embodiments, some of the switch/actuator blocks 104(1,1) through 104(m,n) may include the first switch/actuator unit 16 and the second switch/actuator unit 26 (FIG. 1), while others of the switch/actuator blocks 104(1,1) through 104(m,n) may include the first switch/actuator unit 42 and the second switch/actuator unit 44 (FIG. 2). Each of the groups 102 may include the power switch 12. Alternatively, a power switch 12 in a selected one of the groups 102 may also provide switching of the actuation voltage Vₚ to others of the groups 102.

Still referring to FIG. 7, and also briefly again to FIG. 3, the operation of the actuator group 102 will now be discussed. Considering first a single column of the group 102, a selected one of the switch/actuator blocks 104 (m,n) in the column may be activated by asserting either the operating mode 2 or the operating mode 4, while the remaining switch/actuator blocks 104 (m,n) are maintained in one of the operating modes 1, 3 or 5, so that electrical continuity to ground is maintained. For example, if the switch/actuator block 104 (1,1) is activated by asserting operating mode 2, then the switch/actuator blocks 104 (m+1,1) remain deactivated, with operating modes 1, 3 or 5 asserted.

Turning now to the operation of a single row in group 102, a selected one of the switch/actuator blocks 104 (m,n) may be activated by asserting either the operating mode 2 or the operating mode 4 (depending upon the desired direction of actuation) while the remaining switch/actuator blocks 104 (m,n+1) are maintained in the operating mode 6, in order to prevent a direct electrical path to ground. For example, if the switch/actuator block 104 (1,1) is activated by asserting operating mode 2, then the switch/actuator blocks 104 (1,n+1) remain deactivated, with operating mode 6 asserted.

From the foregoing, it will be appreciated that more than a single one of the switch/actuator blocks 104 (m,n) in a row may be activated simultaneously, while only a single one of the switch/actuator blocks 104 (m,n) in a column may be activated. Since the non-activated switch/actuator blocks 104 (m,n) in a row are maintained in the operating mode 6, a conditioning mode may be applied to a switch/actuator block 104 (m,n) held in operating mode 6 before actuation of the switch/actuator block 104 (m,n). The conditioning mode may be applied in order to assure that the actuator portion of the selected switch/actuator block 104 (m,n) is capable of a complete displacement when actuated. For example, the conditioning mode may include driving the actuator portion in a direction that differs from the actuation direction, then driving the actuator in the intended direction. A post-actuation mode may also be applied to the actuator in the selected switch/actuator block 104 (m,n) following actuation. The post-actuation mode may include, for example, driving the actuator in a direction that is different from the actuation direction in order to assist the actuator to return to the operating mode 6.

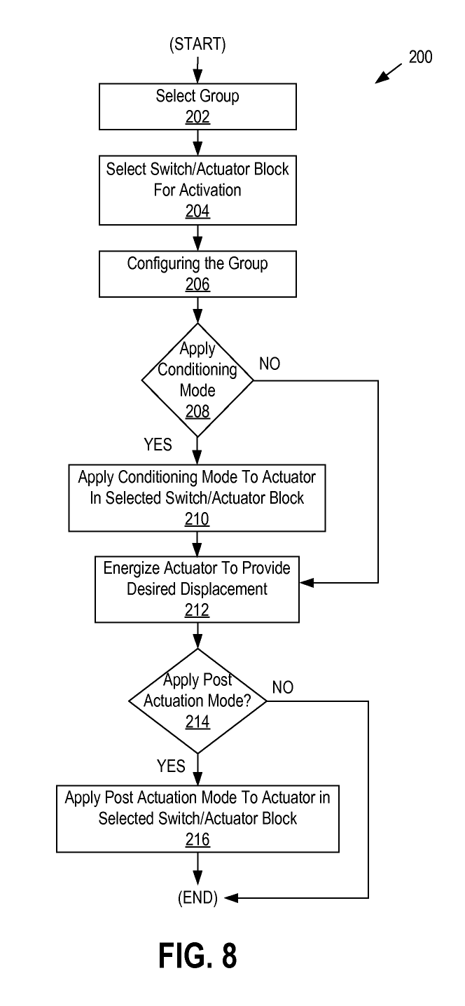

FIG. 8 is a flowchart describing a method 100 of operating an actuator system, according to the various embodiments. With reference also again to FIG. 7, at 202, one or more groups 102 may be selected, for example, by selecting (e.g., energizing) a power switch 12 associated with the selected group 102. At 204, a switch/actuator block 104 (m,n) is selected for activation. At 206, the selected group 102 is configured by setting all switch/actuator blocks 104 (m,n) in the row that includes the selected switch/actuator block 104 (m,n) to the operating mode 6. In addition, all of the switch/actuator blocks 104 (m,n) in the column occupied by the selected switch/actuator block 104 (m,n) may be set to operating modes 1, 3 or 5. At decision 208, a conditioning mode may be applied to the actuator in the selected switch/actuator block 104 (m,n), as shown at 210, whereupon the actuator in the selected switch/actuator block 104 (m,n) may be energized, as shown at 212. Alternatively, the decision 208 may branch to 212, so that the actuator in the selected switch/actuator block 104 (m,n) may be energized without applying the conditioning mode to the actuator. At decision 214, a post actuation mode may be applied to the actuator in the selected switch/actuator block 104 (m,n), as shown at 216. Alternatively, the decision 214 may bypass the application of the post actuation mode.

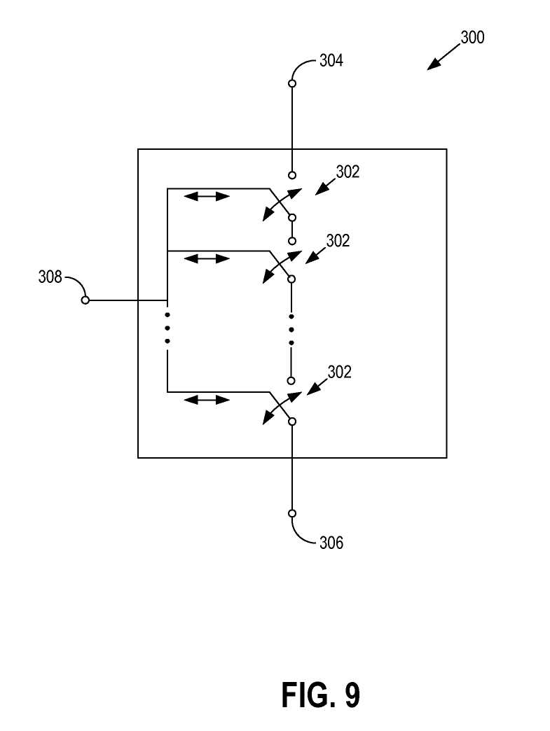

FIG. 9 is a schematic view of a switch 300, according to the various embodiments. The switch 300 may include a plurality of serially-coupled switching elements 302 that are configured to be positioned in an open state and a closed state in unison, so that all of the switching elements 302 are either in the open state or in the closed state simultaneously. Accordingly, the switch 300 may be operable to provide electrical continuity between a first terminal 304 and a second terminal 306 when the switching elements 302 are in the closed state. Correspondingly, electrical continuity between the first terminal 304 and the second terminal 306 may be interrupted when the switching elements 302 are in the open state. The switching elements 302 within the switch 300 may include any suitable switching device, such as a semiconductor device configured to switch electronic signals. For example, the switching elements 202 may include bipolar junction transistors (BJTs), field effect transistors (FETs) or other suitable semiconductor devices or circuits configured to provide electrical switching between the first terminal 304 and the second terminal 306. Accordingly, a third terminal 308 may be provided on the switch 300 in order to provide a suitable current or voltage to the semiconductor switching elements 302 to actuate the switching elements 302 between a conductive and a non-conductive state. The switch 300 may be used in any of the foregoing embodiments as the power switch 12, as shown in FIG. 1, FIG. 2 and FIG. 7. The switch 300 may also be used as the first actuator switch 20 and the second actuator switch 30 shown in FIG. 1, or the first actuator switch 46 and the second actuator switch 50 shown in FIG. 2.

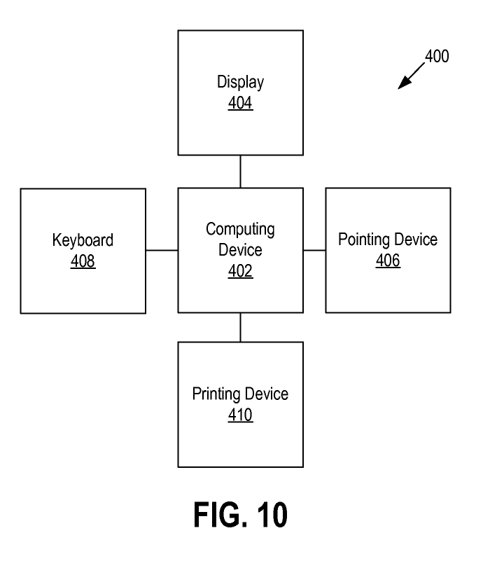

FIG. 10 is a diagrammatic block view of a computer system 400 according to the various embodiments. The system 400 may include a general-purpose computing device 402, which may include any digital device configured to receive programmed instructions and data, and to process the data according to the programmed instructions to provide a useful output. The system 400 may also include various input/output devices operably coupled to the general-purpose computing device 402, which may include a display 404 configured to visually display information to a user, a pointing device 406, such as a trackball or a mouse, that may be used to input commands to the general-purpose computing device 402, and a keyboard 408 that may also be used to input data and commands to the general-purpose computing device 402. A printing device 410 may also be coupled to the general-purpose computing device 402, so that information processed by the device 402 may be graphically reproduced.

The system 400 may include various user-accessible controls that are configured to perform various functions when actuated by a user. For example, the keyboard 408 may include a plurality of keys generally arranged in rows and columns on the keyboard 408 (not shown in FIG. 10). The individual keys on the keyboard 408 generally represent a predetermined character or a predetermined function, and may be configured to be touch-actuated by a user. Still others of the input/output devices may also include touch-actuated devices. For example, the display 404 may include a display surface configured to respond to tactile actuation by a user, so that various commands may be communicated to the general-purpose computing device 402. The pointing device 406 may also be configured to include various touch-actuated devices.

The various embodiments, as discussed in detail above, may be applicable to various haptic-enabled devices. Briefly, a haptic-enabled device may generally include an apparatus that is responsive to a tactile contact by a subject, which, in turn, causes a self-generated action to occur within the apparatus. For example, a haptic-enabled device may apply forces, motions, or vibrations to a user upon the tactile contact. With reference still to FIG. 10, the keyboard 408 of the computer system 400 may be therefore configured to include keys that are haptic-enabled. For example, the bidirectional actuator assembly 10 of FIG. 1 and the unidirectional actuator assembly 40 of FIG. 2 may be incorporated into individual keys within the keyboard 408 so that tactile contact with a selected key location may result in actuation of the selected key. The display 404, the pointing device 406 and the printing device 410 may also include various switches that are configured to be actuated by a user. Accordingly, display 404, the pointing device 406 and the printing device 410 may be configured to include haptic-enabled devices to assist in the actuation of the various switches.

From the foregoing it will be appreciated that, although specific embodiments have been described herein for purposes of illustration, various modifications may be made without deviating from the spirit and scope of the disclosure. Furthermore, where an alternative is disclosed for a particular embodiment, this alternative may also apply to other embodiments even if not specifically stated.

1. A bidirectional actuator assembly, comprising:
a first unit including an electrically deformable material that is selectively coupleable to an activation voltage, wherein the electrically deformable material is configured to provide a displacement in a first direction when the activation voltage is applied to the first unit; and
a second unit serially electrically coupled to the first unit and including an electrically deformable material that is selectively coupleable to the activation voltage, wherein the second unit is configured to provide a displacement in a second direction that is different from the first direction when the activation voltage is applied to the second unit.

2. The bidirectional actuator assembly of claim 1, wherein the electrically deformable material comprises an electroactive polymer material.

3. The bidirectional actuator assembly of claim 1, comprising a power switch configured to selectively couple the activation voltage to the first unit and the second unit.

4. The bidirectional actuator assembly of claim 3, wherein the first unit comprises a first actuator switch electrically coupled in parallel with a first actuator, and the second unit comprises a second actuator switch electrically coupled in parallel with a second actuator, further wherein the first actuator switch and the second actuator switch are coupled to the power switch.

5. The bidirectional actuator assembly of claim 4, wherein at least one of the first actuator switch, the second actuator switch and the power switch includes a plurality of serially coupled switching devices that are configured to be actuated simultaneously.

6. The bidirectional actuator assembly of claim 1, wherein the first direction and the second direction extend in one of approximately opposite directions, and approximately mutually orthogonal directions.

7. A unidirectional actuator assembly, comprising:
at least one unit including an electrically deformable material that is selectively coupleable to an activation voltage, wherein the electrically deformable material is configured to provide a displacement in a selected direction when the activation voltage is applied to the at least one unit.

8. The unidirectional actuator assembly of claim 7, wherein the electrically deformable material comprises an electroactive polymer material.

9. The unidirectional actuator assembly of claim 7, comprising a power switch configured to selectively couple the activation voltage to the at least one unit.

10. The unidirectional actuator assembly of claim 9, wherein the at least one unit comprises a first unit and a serially-coupled second unit, further wherein one of the first unit and the second unit includes the electrically deformable material.

11. The unidirectional actuator assembly of claim 10, wherein the first unit comprises a first actuator switch, and the second unit comprises a second actuator switch electrically coupled in parallel with a second actuator having the electrically deformable material.

12. The unidirectional actuator assembly of claim 11, wherein at least one of the first actuator switch and the second actuator switch includes a plurality of serially coupled switching devices that are configured to be actuated simultaneously.

13. The unidirectional actuator assembly of claim 11, wherein the second actuator is coupled to an elastic element configured to bias the second actuator in a direction opposing the selected direction.

14. A method of operating a bidirectional actuator assembly, comprising:
initializing a first actuator and a second actuator, wherein the first actuator and the second actuator include an electrically deformable material;
applying an actuation voltage to the first actuator to generate a displacement in a first direction; and
applying an actuation voltage to the second actuator to generate a displacement in a second direction that is different from the first direction.

15. The method of claim 14, wherein initializing a first actuator and a second actuator comprises closing a first actuation switch coupled in parallel with the first actuator and closing a second actuation switch coupled in parallel with a second actuator; and
isolating the first actuator and the second actuator from the activation voltage.

16. The method of claim 14, wherein applying an actuation voltage to the first actuator comprises opening a first actuation switch coupled in parallel with the first actuator while closing a second actuation switch coupled in parallel with the second actuator.

17. The method of claim 16, comprising coupling the actuation voltage to the first actuator through a power switch.

18. The method of claim 14, wherein applying an actuation voltage to the second actuator comprises opening an actuation switch coupled in parallel with the second actuator while closing a first actuation switch coupled in parallel with the first actuator.

19. The method of claim 18, comprising coupling the actuation voltage to the second actuator through a power switch.

20. The method of claim 14, wherein applying an actuation voltage to the first actuator comprises resetting the first actuator by closing an actuation switch coupled in parallel with the first actuator and isolating the first actuator from the activation voltage.

21. The method of claim 14, wherein applying an actuation voltage to the second actuator comprises resetting the second actuator by closing an actuation switch coupled in parallel with the second actuator and isolating the second actuator from the activation voltage.

22. The method of claim 14, comprising resetting the first actuator and the second actuator by opening a first actuation switch coupled in parallel with the first actuator and opening a second actuation switch coupled in parallel with the second actuator; and
coupling the activation voltage to the first actuator and the second actuator.

23. A method of operating a unidirectional actuator assembly, comprising:
initializing an actuator that includes an electrically deformable material; and
applying an actuation voltage to the actuator to generate a displacement in a selected direction.

24. The method of claim 23, wherein initializing an actuator comprises closing an actuation switch coupled in parallel with the actuator, and isolating the actuator from the activation voltage.

25. The method of claim 23, wherein applying an actuation voltage to the actuator comprises opening an actuation switch coupled in parallel with the actuator.

26. The method of claim 25, wherein applying an actuation voltage to the actuator comprises closing a power switch to communicate the actuation voltage to the actuator.

27. An actuator system, comprising:
at least one group, further comprising:
a power switch in communication with an activation voltage; and
an array of blocks arranged in rows and columns, each block having an electrically deformable material responsive to the activation voltage and configured to provide a displacement in at least one direction upon actuation.

28. The actuator system of claim 27, wherein at least one of the blocks comprises a first actuator switch electrically coupled in parallel with a first actuator to define a first unit, and a second actuator switch electrically coupled in parallel with a second actuator to define a second unit, further wherein the first unit and the second unit are coupled in series.

29. The actuator system of claim 27, wherein at least one of the blocks comprises a first actuator switch to define a first unit, and a second actuator switch electrically coupled in parallel with a second actuator to define a second unit, further wherein the first unit and the second unit are coupled in series.

30. A method of operating an actuator system, comprising:
selecting a group having an array of blocks arranged in rows and columns;
selecting at least one block within the group, each block having at least one actuator switch electrically coupled in parallel with an actuator having an electrically deformable material configured to generate a displacement in an actuation direction in response to an activation voltage;
configuring the row and the column in the group that includes the selected at least one block; and
applying the activation voltage to the selected at least one block.

31. The method of claim 30, wherein selecting a group comprises closing a power switch coupled to the group.

32. The method of claim 30, wherein configuring the row and the column in the group comprises closing the actuator switches in all non-selected blocks in the column that includes the at least one selected block.

33. The method of claim 30, wherein configuring the row and the column in the group comprises opening the actuator switches in all non-selected blocks in the row that includes the at least one selected block.

34. The method of claim 30, comprising applying a conditioning mode to the at least one selected block.

35. The method of claim 34, wherein applying a conditioning mode comprises applying the activation voltage to the actuator to drive the actuator in a direction that differs from the actuation direction, and driving the actuator in the actuation direction.

36. The method of claim 30, comprising applying a post actuation mode to the at least one selected block.

37. The method of claim 36, wherein applying a post actuation mode comprises applying the activation voltage to the actuator to drive the actuator in a direction that differs from the actuation direction.

38. A computer system, comprising:
a computing device;
at least one input/output device coupled to the computing device including at least one touch-actuated control, further comprising:
an actuator including an electrically deformable material that is selectively coupleable to an activation voltage through an actuator switch, wherein the electrically deformable material is configured to provide a displacement in a selected direction when the activation voltage is applied to the electrically deformable material.

39. The computer system of claim 38, wherein the at least one input/output device includes a display, a keyboard, a pointing device and a printing device.

40. The computer system of claim 38, wherein the at least one input/output device includes a haptic-enabled device.
